(19) United States
(12) Patent Application Publication
(10) Pub. No.: US 2018/0068863 A1
(43) Pub. Date: Mar. 8, 2018

(54) TREATMENT AGENT FOR INHIBITING SUBSTRATE PATTERN COLLAPSE AND TREATMENT METHOD OF SUBSTRATE

(71) Applicant: JSR CORPORATION, Tokyo (JP)

(72) Inventors: Kenji FUJITA, Tokyo (JP); Yoshio TAKIMOTO, Tokyo (JP); Kang-go CHUNG, Tokyo (JP)

(73) Assignee: JSR CORPORATION, Tokyo (JP)

(21) Appl. No.: 15/812,005

(22) Filed: Nov. 14, 2017

Related U.S. Application Data
(63) Continuation of application No. PCT/JP2016/063189, filed on Apr. 27, 2016.

(30) Foreign Application Priority Data
May 15, 2015 (JP) 2015-100339
Nov. 5, 2015 (JP) 2015-218006

(51) Int. Cl. H01L 21/306; H01L 21/02

(52) U.S. Cl. CPC H01L 21/30604; H01L 21/0206; H01L 21/02101

(57) ABSTRACT

A treatment agent for inhibiting substrate pattern collapse contains a polymer and a polar solvent. A treatment method of a substrate includes: applying the treatment agent onto a substrate having a pattern formed thereon; and drying the treatment agent applied onto the substrate. The polymer is preferably a hydrophilic polymer. In addition, the polymer preferably has at least one functional group selected from a hydroxy group, a carboxy group, an amide group, an amino group, a sulfo group and an aldehyde group. Furthermore, the polymer is preferably one selected from a vinyl polymer, a polysaccharide, a polyester, a polyether and a polyamide.

### CROSS-REFERENCE TO RELATED APPLICATIONS

The present application is a continuation application of International Application No. PCT/JP2016/063189, filed Apr. 27, 2016, which claims priority to Japanese Patent Application No. 2015-100339, filed May 15, 2015 and to Japanese Patent Application No. 2015-218006, filed Nov. 5, 2015. The contents of these applications are incorporated herein by reference in their entirety.

### BACKGROUND OF THE INVENTION

### Field of the Invention

The present invention relates to a treatment agent for inhibiting substrate pattern collapse, and a treatment method of a substrate.

### Discussion of the Background

In production processes of a semiconductor device, a micro-electromechanical system (MEMS) and the like, substrates (objects to be treated) are treated with liquid. For example, a substrate, a laminated film, a resist film, or the like is patterned in a liquid treatment, etc., whereby a fine structure is formed on the substrate. In addition, impurities and residues left on the substrate are removed by washing with liquid. These steps are performed in combination. After the liquid treatment, the fine structure formed on the substrate may collapse upon removal of the liquid, due to the surface tension of the liquid.

Meanwhile, microfabrication of substrate patterns has been further in progress along with further miniaturization, enhanced integration or increased speed of semiconductor devices for use in networks and/or digital household appliances. Due to an increase in the aspect ratio with advanced microfabrication of substrate patterns, a drawback may arise that a substrate pattern is likely to collapse when the gas-liquid interface passes through the pattern while a wafer is dried after being washed or rinsed. Since no practical solution to the drawback is attained, it is necessary to, for example, design a pattern that is resistant to collapse, for further miniaturization, enhanced integration or increased speed of semiconductor devices and/or micromachines, resulting in significant impairment of the freedom in the design of patterns.

Japanese Unexamined Patent Application, Publication No. 2008-198958 discloses a procedure of inhibiting the substrate pattern collapse, i.e., a technique of changing a washing liquid from water to 2-propanol before the gas-liquid interface passes through the pattern. However, the technique is reportedly subject to, for example, the limitation that an adaptable aspect ratio of the pattern is no greater than 5.

Additionally, Japanese Patent No. 4403202 discloses a cleaning procedure in which modification of a wafer surface having an uneven pattern forming from a film containing silicon by oxidization or the like is conducted and then a water-repellent protecting film is formed on the surface by using a water-soluble surfactant or a silane coupling agent, thereby reducing the capillary force and preventing pattern collapse.

Furthermore Japanese Unexamined Patent Application, Publication No. 2010-129932 and PCT International Publication No. 10/47196 Pamphlet disclose a technique for preventing substrate pattern collapse by conducting a hydrophobilization treatment through the use of a treatment liquid containing: a silylation agent such as N,N-dimethylaminotrimethylsilane; and a solvent.

### SUMMARY OF THE INVENTION

According to one aspect of the present invention, a treatment agent for inhibiting substrate pattern collapse includes a polymer and a polar solvent.

According to another aspect of the present invention, a treatment method of a substrate includes applying a treatment agent which includes a polymer and a polar solvent onto a substrate having a pattern formed thereon, and drying the treatment agent applied onto the substrate.

### DESCRIPTION OF EMBODIMENTS

Embodiments of the present invention provide a treatment agent for inhibiting substrate pattern collapse and a treatment method of a substrate through the use of the treatment agent as in the following.

(1) A treatment agent for inhibiting substrate pattern collapse, containing a polymer and a polar solvent.

(2) The treatment agent for inhibiting substrate pattern collapse according to (1), the polymer being a hydrophilic polymer.

(3) The treatment agent for inhibiting substrate pattern collapse according to (1) or (2), the polymer having at least one type of functional group selected from a hydroxy group, a carboxy group, an amide group, an amino group, a sulfo group and an aldehyde group.

(4) The treatment agent for inhibiting substrate pattern collapse according to any one of (1) to (3), the polymer being at least one selected from a vinyl polymer, a polysaccharide, a polyester, a polyether and a polyamide.

(5) The treatment agent or inhibiting substrate pattern collapse according to any one of (1) to (4), the polymer containing a hydroxy group-containing vinyl polymer.

(6) The treatment agent for inhibiting substrate pattern collapse according to any one of (1) to (5), a weight average molecular weight of the polymer being no less than 1,000 and no greater than 50,000.

(7) The treatment agent for inhibiting substrate pattern collapse according to any one of (1) to (6), the polar solvent being water or a polar organic solvent.

(8) The treatment agent for inhibiting substrate pattern collapse according to (7), the polar organic solvent being at least one selected from an alcohol, an alkyl ether of a polyhydric alcohol, a hydroxycarboxylic acid ester and a hydroxy ketone.

(9) The treatment agent for inhibiting substrate pattern collapse according to any one of (1) to (8), the treatment agent further containing a surfactant.

(10) The treatment agent for inhibiting substrate pattern collapse according to any one of (1) to (9), a content of the polymer being no less than 0.1% by mass and no greater than 50% by mass.

(11) The treatment agent for inhibiting substrate pattern collapse according to any one of (1) to (10), which is for use in embedment.

(12) A treatment method of a substrate, including:

applying the treatment agent according to any one of (1) to (11) onto a substrate having a pattern formed thereon;

and drying the treatment agent applied onto the substrate.

(13) The treatment method of a substrate according to (12), the substrate containing a silicon atom or a metal atom.

According to the embodiments of the present invention, the treatment agent for inhibiting substrate pattern collapse, having a superior ability to inhibit substrate pattern collapse even in the field of fine structures such as semiconductor devices and micro-electromechanical systems, and the treatment method of a substrate through the use of the treatment agent are provided.

Hereinafter, embodiments of the present invention will be described, but the present invention is not in any way limited to the embodiments. In other words, the embodiments which may be altered and/or modified as appropriate on the basis of the common knowledge of one of ordinary skill in the art within a range not departing from principles of the present invention are to be construed to fall within the scope of the present invention.

### Treatment Agent for Inhibiting Substrate Pattern Collapse

The treatment agent for inhibiting substrate pattern collapse according to an embodiment of the present invention contains a polymer (hereinafter, may be also referred to as “(A) polymer” or “polymer (A)”) and a polar solvent (hereinafter, may be also referred to as “(B) polar solvent” or “polar solvent (B)”). The treatment agent for inhibiting substrate pattern collapse may contain as a favorable component, (C) an additive (hereinafter, may be also referred to as “additive (C)”) such as a surfactant, and may also contain other optional component(s) within a range not leading to impairment of the effects of the present invention. Each component will be described below.

(A) Polymer

The polymer (A) is not particularly limited and any one may be used as long as it is a polymer. The polymer (A) is exemplified by a vinyl polymer, a polysaccharide, a polyester, a polyether, a polyamide, and the like. The polymer (A) may be used either alone of one type, or in combination of two or more types thereof.

The polymer (A) is preferably a hydrophilic polymer in light of the embedment property into the substrate pattern and the ability to inhibit pattern collapse. In light of the improvement of the embedment property and the ability to inhibit pattern collapse, it is preferred that, when being in dry powder form, the hydrophilic polymer is homogeneously soluble in water or alcohol at a concentration of no less than 0.1% by mass at 25° C. under an atmospheric pressure. In the case of using a hydrophilic polymer that is not homogeneously soluble at a concentration of no less than 0.1% by mass at 25° C. under an atmospheric pressure, the embedment property into the substrate pattern and the ability to inhibit patter collapse may not be sufficiently improved.

In addition, the polymer (A) preferably has at least one type of functional group selected from a hydroxy group, a carboxy group, an amide group, an amino group, a sulfo group and an aldehyde group. The lower limit of the proportion of the structural units having at least one type of functional group selected from a hydroxy group, a carboxy group, an amide group, an amino group, a sulfo group and an aldehyde group with respect to the total structural units constituting the polymer (A) is preferably 10 mol %, more preferably 30 mol %, and still more preferably 50 mol %. In the polymer (A), the functional group may be contained in a state of being the functional group per se, in a state of being dissociated into an ionic group and a counterion, or in a state where the dissociated ionic group and the dissociated counterion of the functional group are rebonded.

The polymer having a hydroxy group is exemplified by polysaccharides, polyhydroxy acids and salts thereof, polyalkylene glycols, hydroxy group-containing vinyl polymers, and the like. Of these, hydroxy group-containing vinyl polymers are preferred.

Exemplary polysaccharides include alginic acid, pectic acid, hydroxypropyl cellulose, carboxymethyl cellulose, agar, curdlan, pullulan, and the like.

Exemplary polyhydroxy acids and salts thereof include polymalic acids, ammonium polymalate, and the like.

Exemplary polyalkylene glycols include polyethylene glycol, polypropylene glycol, and the like.

Exemplary hydroxy group-containing vinyl polymers include a polyvinyl alcohol, a hydroxy group-containing methacrylic polymer, a hydroxy-group acrylic polymer, and the like. Examples of the hydroxy group-containing methacrylic polymer include poly(2-hydroxyethyl methacrylate), poly(2-hydroxypropyl methacrylate), poly(2-hydroxybutyl methacrylate), and the like. Examples of the hydroxy group-containing acrylic polymer include poly(2-hydroxyethyl acrylate), poly(2-hydroxypropyl acrylate), poly(2-hydroxybutyl acrylate), and the like.

The polymer having a carboxy group is exemplified by polyamino acids and salts thereof, the aforementioned polyhydroxy acids and salts thereof, polyamide acids and salts thereof, carboxy group-containing vinyl polymers and salts thereof, and the like.

Examples of the polyamino acid and the salt thereof include polyaspartic acids, polyglutamic acids, polylysine, and the like.

Examples of the polyamide acid and the salt thereof include polyamide acids, polyamide acid ammonium salts, and the like.

Examples of the carboxy group-containing vinyl polymer and the salt thereof include polyacrylic acids, polyacrylic acid ammonium salts, polymethacrylic acids, polymethacrylic acid ammonium salts, polymaleic acids, polyitaconic acids, polyfumaric acids, poly(p-styrene carboxylic acid), and the like.

The polymer having an amide group is exemplified by the aforementioned polyamide acids and the salts thereof, amide group-containing vinyl polymers, and the like.

Examples of the amide group-containing vinyl polymer include polyacrylamide, polydimethylacrylamide, poly(N-isopropylacrylamide), aminopolyacrylamide, and the like.

The polymer having an amino group is exemplified by amino group-containing vinyl polymers, polyethylene imine, polyoxazoline, and the like.

Examples of the amino group-containing vinyl polymer include polyvinylamine, polyallylamine, polyvinylpyrrolidone, and the like.

Examples of the polyoxazoline include polymethyloxazoline, polyethyloxazoline, polyhydroxypropyloxazoline, and the like.

The polymer having a sulfo group is exemplified by sulfo group-containing vinyl polymers, and the like.

Examples of the sulfo group-containing vinyl polymer include polyvinylsulfonic acids, poly(p-styrene sulfonic acid), polyisoprene sulfonic acids, and the like.

The polymer having an aldehyde group is exemplified by polyacrolein, polyglyoxylic acid, and the like.

These polymers may be used either alone of one type, or in combination of two or more types thereof.

The lower limit of the weight average molecular weight of the polymer (A) is preferably 1,000, more preferably 1,500, still more preferably 2,000, and particularly preferably 4,000 in light of the embedment property into the substrate pattern. The upper limit of the weight average molecular weight of the polymer (A) is not particularly limited, and preferably 1,000,000, more preferably 300,000, still more preferably 100,000, and particularly preferably 50,000 in light of the embedment property into the substrate pattern and the ability to inhibit patter collapse. The weight average molecular weight of the polymer (A) may be determined by gel permeation chromatography through the use of a calibration curve produced by using a standard polystyrene.

The upper limit of the content of a component having a molecular weight of no greater than 500 (the content of a low molecular weight polymer) in the polymer (A) is preferably 0.1% by mass, more preferably 0.08% by mass, and still more preferably 0.05% by mass. When the content of the low molecular weight polymer in the polymer (A) falls within the above range, the amount of sublimated matter generated in the step of subjecting to a baking treatment a coating film of the treatment agent for inhibiting substrate pattern collapse can be reduced, whereby inhibition of contamination of the device and/or the substrate by the sublimated matter is enabled. The lower limit of the content of the low molecular weight polymer in the polymer (A) is, for example, 0.01% by mass.

The content of the low molecular weight polymer in the polymer (A) can be determined by using a gas chromatograph mass spectrometer.

The lower limit of the content of the polymer (A) in the treatment agent for inhibiting substrate pattern collapse is preferably 0.1% by mass, more preferably 1% by mass, and still more preferably 3% by mass. The upper limit of the content of the polymer (A) is preferably 50% by mass, more preferably 30% by mass, still more preferably 25% by mass, and particularly preferably 15% by mass. In the treatment agent for inhibiting substrate pattern collapse, the polymer (A) may be contained in a state of being the polymer (A) per se, in a state of being dissociated, or in a state where the dissociated polymer (A) is rebonded to a counterion.

(B) Polar Solvent

The treatment agent for inhibiting substrate pattern collapse contains the polar solvent (B). The polar solvent (B) is not particularly limited, and is preferably water and a polar organic solvent.

The polar organic solvent is not particularly limited. In light of the improvement of the embedment property into the substrate pattern and the ability to inhibit pattern collapse, alcohols, alkyl ethers of a polyhydric alcohol, hydroxycarboxylic acid esters, hydroxy ketones, carboxylic acids, ethers, ketones, nitriles, amides and amines are preferred; alcohols, alkyl ethers of a polyhydric alcohol, hydroxycarboxylic acid esters and hydroxy ketones are more preferred; and protonic organic solvents such as alcohols, monoalkyl ethers of a polyhydric alcohol, hydroxycarboxylic acid esters and hydroxy ketones are still more preferred.

Examples of the alcohol include: monohydric alcohols such as methanol, ethanol, propanol, n-butanol, n-pentanol, n-hexanal and isopropanol; and polyhydric alcohols such as ethylene glycol, propylene glycol, diethylene glycol, dipropylene glycol, triethylene glycol and tripropylene glycol. Of these, methanol and isopropanol are preferred, and isopropanol is particularly preferred.

Examples of the alkyl ether of a polyhydric alcohol include: monoalkyl ethers of a polyhydric alcohol such as ethylene glycol monoethyl ether, propylene glycol monomethyl ether, ethylene glycol monopropyl ether, propylene glycol monoproplyl ether, ethylene glycol monobutyl ether and propylene glycol monobutyl ether; polyalkyl ethers of a polyhydric alcohol such as ethylene glycol dimethyl ether, propylene glycol dimethyl ether, ethylene glycol diethyl ether, propylene glycol diethyl ether, ethylene glycol dipropyl ether, propylene glycol dipropyl ether, ethylene glycol dibutyl ether and propylene glycol dibutyl ether; and the like.

Examples of the hydroxycarboxylic acid ester include methyl glycolate, ethyl glycolate, methyl lactate, ethyl lactate, methyl hydroxypropionate, ethyl hydroxypropionate, methyl hydroxybutyrate, ethyl hydroxybutyrate, and the like.

Examples of the hydroxy ketones include: α-hydroxy ketones such as hydroxyacetone, 1-hydroxy-2-butanone, 1-hydroxy-2-pentanone, 3-hydroxy-2-butanone and 3-hydroxy-3-pentanone; β-hydroxy ketones such as 4-hydroxy-2-butanone, 3-methyl-4-hydroxy-2-butanone, diacetone alcohol, 4-hydroxy-5,5-dimethyl-2-hexanone; 5-hydroxy-2-pentanone; 5-hydroxy-2-hexanone; and the like.

Examples of the carboxylic acid include formic acid, acetic acid, and the like.

Examples of the ether include tetrahydrofuran, 1,4-dioxane, dimethoxyethane, polyethylene oxide, and the like.

Examples of the ketone include acetone, methyl ethyl ketone, and the like.

Examples of the nitrile include acetonitrile and the like.

Examples of the amide include N,N-dimethylformamide, N,N-dimethylacetamide, and the like.

Examples of the amine include triethylamine, pyridine, and the like.

Of these polar solvents (B), water, alcohols, alkyl ethers of a polyhydric alcohol, hydroxycarboxylic acid esters and hydroxy ketones are preferred; and water, isopropanol, diacetone alcohol, diacetone alcohol, propylene glycol monomethyl ether, propylene glycol monoethyl ether, methyl lactate and ethyl lactate are particularly preferred, in light of the improvement of the embedment property into the substrate pattern and the ability to inhibit pattern collapse.

The polar solvent (B) may be used either alone of one type, or as a mixture of two or more types thereof.

The polar solvent (B) is preferably soluble in water at a concentration of no less than 1% by mass at 20° C. in light of the improvement of the embedment property into the substrate pattern and the ability to inhibit pattern collapse. Furthermore, the polar solvent (B) preferably has a relative permittivity of no less than 6.0 in light of the improvement of the embedment property into the substrate pattern and the ability to inhibit pattern collapse.

(C) Additive

As needed, the treatment agent for inhibiting substrate pattern collapse may also contain the additive (C) as an optional component within the range not leading to impairment of the object of the present invention.

As the additive (C), a surfactant may be contained in light of the improvement of the coating property, the embedment property into the substrate pattern and the ability to inhibit pattern collapse.

The surfactant is exemplified by a nonionic surfactant, a cationic surfactant, an anionic surfactant, and the like.

Specifically, the nonionic surfactant is exemplified by: ether type surfactants such as polyoxyethylene alkyl ethers; ether-ester type surfactants such as polyoxyethylene ethers of a glycerin ester; ester type surfactants such as polyethylene glycol fatty acid esters, glycerin esters and sorbitan esters, and the like. Examples of the commercially available product of the nonionic surfactant include: Newcol 2320, Newcol 714-F, Newcol 723, Newcol 2307 and Newcol 2303 (all available from Nipon Nyukazai Co., Ltd.); Pionin D-1107-S, Pionin D-1007 and Pionin D-1106-DIR and Newkalgen TG310 (all available from TAKEMOTQ OIL & FAT Co., Ltd); and the like.

Specifically, the cationic surfactant is exemplified by aliphatic amine salts, aliphatic ammonium salts, and the like.

Specifically, the anionic surfactant is exemplified by: carboxylic acid salts such as fatty acid soap and alkyl ether carboxylic acid salts; sulfonic acid salts such as alkylbenzene sulfonic acid salts, alkylnaphthalene sulfonic acid salts and α-olefin sulfonic acid salts; sulfuric acid ester salts such as higher alcohol sulfuric acid ester salts and alkylether sulfuric acid salts; phosphoric acid ester salts such as alkyl phosphate esters; and the like.

As the surfactant, the nonionic surfactant is particularly preferred in light of the coating property and the embedment property into the substrate pattern. These surfactants may be used either alone of one type or in combination of two or more types thereof.

The lower limit of the content of the surfactant in the treatment agent for inhibiting substrate pattern collapse is preferably 0.0001% by mass, more preferably 0.001% by mass, still more preferably 0.01% by mass, and particularly preferably 0.05% by mass. The upper limit of the content of the surfactant is preferably 1% by mass, more preferably 0.5% by mass, and still more preferably 0.2% by mass.

The upper limit of the total metal content in the treatment agent for inhibiting substrate pattern collapse is preferably 30 ppb by mass, more preferably 20 ppb by mass, and still more preferably 10 ppb by mass in light of further reducing contamination of the substrate pattern. The lower limit of the total metal content is not particularly limited, and may be, for example, 1 ppb by mass.

The metal which may be contained in the treatment agent for inhibiting substrate pattern collapse is exemplified by sodium, potassium, magnesium, calcium, copper, aluminum, iron, manganese, tin, chromium, nickel, zinc, lead, titanium, zirconium, silver, platinum, and the like. The metal may be contained in the treatment agent for inhibiting substrate pattern collapse in any form such as a metal cation, a metal complex, a simple metal and an ionic compound, without being particularly limited thereto. Each metal content and the total metal content in the treatment agent for inhibiting substrate pattern collapse can be determined by, for example, inductively coupled plasma-mass spectrometry (ICP-MS).

As the procedure of adjusting the total metal content in the treatment agent for inhibiting substrate pattern collapse to fall within the above range, a procedure may be adopted which involves filtering the treatment agent for inhibiting substrate pattern collapse having a metal content of greater than 30 ppb by mass through, e.g., a filter including a nylon 66 film as a filtering medium, an ion exchange filter, or a filter using the absorption effect produced by zeta potentials.

The procedure of reducing the content of the metal and the like in the treatment agent for inhibiting substrate pattern collapse is not limited to the above procedure, and a well-known procedure may be adopted which is exemplified by: chemical purification processes such as washing with water and liquid-liquid extraction; combinations of the chemical purification process with a physical purification process such as ultrafiltration or centrifugal separation; and the like.

### Production Method of Treatment Agent for Inhibiting Substrate Pattern Collapse

The treatment agent for inhibiting substrate pattern collapse can be produced by mixing the polymer (A), the polar solvent (B) and as needed, other optional component(s) such as the additive (C), and thereafter filtering the solution thus obtained through a filter having a pore size of about 0.2 μm. The lower limit of the solid content concentration of the treatment agent for inhibiting substrate pattern collapse is preferably 0.1% by mass, more preferably 1% by mass, and still more preferably 3% by mass. The upper limit of the solid content concentration is preferably 50% by mass, more preferably 30% by mass, still more preferably 25% by mass, and particularly preferably 15% by mass.

The production method of the treatment agent for inhibiting substrate pattern collapse preferably includes filtering a solution containing the polymer (A) through a nylon filter, an ion exchange filter or a filter using the absorption effect produced by zeta potentials. When the solution containing the polymer (A) is filtered through a nylon filter, an ion exchange filter or a filter using the absorption effect produced by zeta potentials, the metal content in the treatment agent for inhibiting substrate pattern collapse can be reduced conveniently and reliably, so that the treatment agent for inhibiting substrate pattern can be produced easily and reliably while an increase in cost of the treatment agent for inhibiting substrate pattern collapse is inhibited.

After the treatment agent for inhibiting substrate pattern collapse is baked on the silicon substrate in an ambient air at 120° C. for 1 min, the contact angle for water on the surface of a coating film thus obtained (at 25° C., 50% RH) is preferably less than 90°, and more preferably no greater than 70°. When the contact angle for water is no less than 90°, the embedment property into the substrate pattern and the ability to inhibit patter collapse may not be sufficiently improved.

### Treatment Method of Substrate

A treatment method of a substrate according to another embodiment of the present invention includes: applying, onto a substrate having a pattern formed thereon, the treatment agent for inhibiting substrate pattern collapse of the above embodiment; and drying the treatment agent applied onto the substrate. More specifically, the treatment agent for inhibiting substrate pattern collapse is used in a step after wet etching or dry etching. The treatment method of a substrate preferably involves: carrying out, subsequent to wet etching or dry etching, at least one step selected from a washing step of washing the substrate with a washing liquid and a rinsing step of rinsing the substrate with a rinse agent; and thereafter applying, onto the substrate having a pattern formed thereon, the treatment agent for inhibiting substrate pattern collapse described above and drying the treatment agent. In this case, it is more preferred that a coating film is formed in such a manner that the treatment agent for inhibiting substrate pattern collapse is applied while the washing liquid or the rinse agent is retained on the substrate so as to replace the washing liquid or the rinse agent by the treatment agent.

The washing liquid is exemplified by a sulfate ion-containing stripping agent, a chloride ion-containing washing liquid, a fluoride ion-containing washing liquid, a nitrogen compound-containing alkaline washing liquid, a phosphoric acid-containing washing liquid, and the like. The washing liquid preferably contains hydrogen peroxide. Washing steps through the use of two or more kinds of washing liquids may be carried out sequentially. As the sulfate ion-containing stripping agent, a sulfuric acid peroxide mixture (SPM) obtained by mixing hydrogen peroxide and sulfuric acid is preferred and suited for removal of organic matters such as a resist. As the chloride ion-containing washing liquid, an aqueous mixed solution containing hydrogen peroxide and hydrochloric acid (SC-2) is preferred and suited for removal of metal. Examples of the fluoride ion-containing washing liquid include an aqueous mixed solution containing hydrofluoric acid and ammonium fluoride. As the nitrogen compound-containing alkaline washing liquid, an aqueous mixed solution containing hydrogen peroxide and ammonia (SC-1) is preferred and suited for removal of particles. Examples of the rinse agent include ultra pure water.

The process for applying onto the substrate the treatment agent for inhibiting substrate pattern collapse is not particularly limited, and for example, an appropriate process such as a spin-coating process, a cast coating process and a roll coating process may be employed.

The process for drying the coating film is not particularly limited, and generally involves a heating treatment in an ambient air atmosphere. In addition, the lower limit of the heating temperature is not particularly limited, and is preferably 40° C., more preferably 50° C., and still more preferably 60° C. The upper limit of the heating temperature is preferably 200° C., and more preferably 150° C. The lower limit of the heating time period is preferably 15 sec, more preferably 30 sec, and still more preferably 45 sec. The upper limit of the heating time period is preferably 1,200 sec, more preferably 600 sec, and still more preferably 300 sec.

By applying onto the substrate having a pattern formed thereon, the treatment agent for inhibiting substrate pattern, and drying the same in such a manner, embedment of the polymer contained in the treatment agent for inhibiting substrate pattern collapse into recessed portions of the substrate pattern is enabled, thereby enabling pattern collapse to be inhibited that may cause a contact between adjacent patterns.

A superior ability to inhibit substrate pattern collapse is attained through the application of the treatment method of a substrate to patterns formed on the substrate, i.e., fine patterns exemplified by: line and space patterns each having a pattern size of no greater than 300 nm, no greater than 150 nm, no greater than 100 nm or no greater than 50 nm; and fine patterns each having a cylindrical or columnar structure, with the pattern-to-pattern distance being no greater than 300 nm, no greater than 150 nm or no greater than 100 nm.

A superior ability to inhibit substrate pattern collapse is also attained through the application of the treatment method of a substrate to patterns formed on the substrate, i.e., fine patterns each having a pattern configuration involving: a height of no less than 100 nm, no less than 200 nm or no less than 300 nm; a width of no greater than 50 nm, no greater than 40 nm or no greater than 30 nm; and an aspect ratio (the height of the pattern:the width of the pattern) of no less than 3, no less than 5 or no less than 10.

The coating film formed by the application of the treatment agent for inhibiting substrate pattern collapse preferably enables embedment into recessed portions of the pattern. Thus, the treatment agent for inhibiting substrate pattern collapse can be suitably used for embedment. The thickness of the coating film is not particularly limited, and the lower limit of the average thickness of the coating film on the surface of each raised portion is preferably 0.01 μm, more preferably 0.02 μm, and still more preferably 0.05 μm. The upper limit of the average thickness is preferably 5 μm, more preferably 3 μm, still more preferably 2 μm, and particularly preferably 0.5 μm.

The treatment agent for inhibiting substrate pattern collapse is applicable to a wide variety fine structures regardless of their types. The substrate pattern is not particularly limited as long as it is formed on a substrate and is other than a resist pattern. The substrate pattern preferably contains a silicon atom or a metal atom, and in particular, more preferably includes a metal, a metal nitride, a metal oxide, a silicon oxide and/or silicon.

The coating film formed on the substrate from the treatment agent for inhibiting substrate pattern can be removed in a gaseous phase. For the removal, a heat treatment, a plasma treatment, ashing, ultraviolet irradiation, electron beam irradiation, etc. may be carried out.

### EXAMPLES

Hereinafter, the embodiments of the present invention will be described in more detail by way of Examples, but the present invention is not in any way limited to these Examples.

### Mw and Mn

The weight average molecular weight (Mw) and the number average molecular weight (Mn) of the polymer were determined by using: a gel permeation chromatograph (“HLC-8220” available from Tosoh Corporation) equipped with GPC columns (“G2000HXL”×1, “G3000HXL”×1, and“G4000HHR”) available from Tosoh Corporation; and a polystyrene standard sample (“Easical PS-1” available from Agilent Technologies Japan, Ltd.), under analytical conditions involving a flow rate of 1.00 mL, an elution solvent of tetrahydrofuran, and a column temperature of 40° C.

### Content of Low Molecular Weight Polymer in (A) Polymer

The content of the low molecular weight polymer in the polymer (A), i.e., the content (% by mass) of components having a molecular weight of no greater than 500 was determined by the following procedure.

Into an eggplant-shape flask, 50 g of a solution containing the polymer (A) was weighed, and the solvent was distilled off by using an evaporator at a bath temperature of 30° C. for two days. Thereafter, the mass of the remaining solid content was determined, and the solid content concentration of the solution containing the polymer (A) (hereinafter denoted by (a), unit: % by mass) was calculated.

On the basis of the solid content concentration thus obtained, 100 g of the solution containing the polymer (A) was concentrated to give a solid content concentration of 25% in a manner similar to the above operation. The concentrated liquid thus obtained was slowly added dropwise to ten times by mass of n-hexane being stirred, to permit deposition of insoluble components. The suspension thus obtained was filtered through a 0.1 μm membrane filter, and thereafter the mass of the filtrate thus obtained (hereinafter denoted by (1), unit: g) was determined.

By using an evaporator, n-hexane was completely distilled off from the filtrate, and the mass of the residue thus obtained was determined to calculate the concentration of residual components in the filtrate (hereinafter denoted by (2), unit: %).

Each residual component was identified by using a gas chromatograph mass spectrometer (GC-MS: “ITQ900” available from Thermo Fisher Scientific K.K.), and the components corresponding to the low molecular weight polymer were selected. In addition, the proportion of the components corresponding to the low molecular weight polymer in the residue (hereinafter denoted by (3), unit: % by mass) was determined by using GC (GC equipped with a flame ionization detector (FID), i.e., “TRACE GC Ultra” available from Thermo Fisher Scientific K.K.).

The content (% by mass) of the low molecular weight polymer in the polymer (A) was determined from the obtained values (a), (1), (2) and (3) by using the following equation (L).

$$\begin{matrix} the content ( \% by mass ) of the low \\ molecular weight polymer in the polymer ( A ) \\ = the mass of the low molecular weight polymer in the solution \\ containing the polymer ( A ) / \\ ( the mass of the solution containing the polymer ( A ) ( 100 g ) \times \\ the solid content concentration ( \% by mass ) of the \\ solution containing the polymer ( A ) ) \times 100 \\ = [ ( 1 ) \times \{ ( 2 ) / 100 \} \times \{ ( 3 ) / 100 \} ] \times 100 / ( 100 \times \{ ( A ) / 100 \} ) \\ = ( 1 ) \times ( 2 ) \times ( 3 ) / ( ( a ) \times 100 )\end{matrix} \qquad ( L )$$

### Metal Content

The treatment agent for inhibiting substrate pattern collapse was diluted 10-fold with nitric acid to determine the content of each metal contained in the treatment agent for inhibiting substrate, i.e., Na, K, Mg, Ca, Cu, Al, Fe, Mn, Sn, Cr, Ni, Zn, Pb, Ti, Zr, Ag and Pt, by using ICP-MS (“ELAN DRCII” available from PerkinElmer Inc.), and thereafter the total metal content was calculated from the determined values of the metal content.

### Synthesis Example 1

In a nitrogen atmosphere, 15 g of 2-hydroxyethyl methacrylate and 0.87 g of 1-thioglycerol, which is a compound for introducing a water-soluble functional group to the end of the polymer and adjusting the molecular weight, were dissolved in 35 g of commercially available isopropanol (IPA) in a 100 mL three-neck flask, and thereafter 0.06 g of dimethyl-2,2′-azobisisobutyrate as a polymerization initiator was added thereto. The mixture was heated to 80° C. to start polymerization. After the mixture was stirred for 7 hrs, heating was stopped to cool the mixture, whereby an isopropanol solution of a polymer (A-1) was obtained. The polymer (A-1) thus obtained had an Mw of 3,100, an Mw/Mn of 1.9, and the content of the low molecular weight polymer was 0.08% by mass.

### Preparation of Treatment Agent for Inhibiting Substrate Pattern Collapse

The components other than the polymer (A-1) that were used to prepare the treatment agents for inhibiting substrate pattern collapse are shown below.

(A) Polymer

A-2: polyacrylic acid having a weight average molecular weight of 5,000 (available from Wako Pure Chemical Industries, Ltd.)

A-3: polyacrylic acid having a weight average molecular weight of 25,000 (available from Wako Pure Chemical Industries, Ltd.)

A-4: polyacrylic acid having a weight average molecular weight of 250,000 (available from Wako Pure Chemical Industries, Ltd.)

A-5: polyacrylic acid ammonium having a weight average molecular weight of 6,000 (“ARON A-30SL” available from Toagosei. Co., Ltd.)

A-6: polyvinyl alcohol having a degree of polymerization of 500 (available from Wako Pure Chemical Industries, Ltd.)

A-7: polyvinylpyrrolidone having a viscosity average molecular weight of 10,000 (“P0471” available from Tokyo Chemical Industry Co., Ltd.)

A-8: polyethylene imine having a weight average molecular weight of 10,000 (available from Wako Pure Chemical Industries, Ltd.)

A-9: pullulan (“P0978” available from Tokyo Chemical Industry Co., Ltd.) A-10: hydroxypropyl cellulose having a viscosity of 3 to 6 mPa·s (2% by mass aqueous solution, 20° C.) (“P0473” available from Tokyo Chemical Industry Co., Ltd.)

(B) Solvent

B-1: water

B-2: isopropanol (IPA)

B-3: methanol (MeOH)

B-4: propylene glycol monomethyl ether

B-5: propylene glycol monoethyl ether

B-6: methyl lactate

B-7: ethyl lactate

B-8: diacetone alcohol

(C) Additive

C-1: surfactant (“Newcol 2307” available from Nippon Nyukazai Co., Ltd.)

### Example 1

Solvent substitution of the isopropanol solution of the polymer (A-1) obtained in Synthesis Example 1 gave an aqueous solution by the use of an evaporator. The aqueous solution of the polymer (A-1) thus obtained was diluted with water to have the composition shown in Table 1. Subsequently, the aqueous solution of the polymer (A-1) thus obtained was stirred to completely dissolve the polymer (A-1), and thereafter the aqueous solution was filtered through a hydrophilized 0.2 μm PTFE filter (“DISMIC25JP” available from ADVANTEC), whereby the treatment agent for inhibiting substrate pattern collapse of Example 1 was prepared. The total metal content in the treatment agent for inhibiting substrate pattern collapse of Example 1 was 15 ppb by mass. In Table 1, “-” indicates that the relevant component was not used.

### Example 2

The treatment agent for inhibiting substrate pattern collapse was prepared as in Example 1 except that the aqueous solution of the polymer (A-1) obtained was diluted with water and isopropanol to have the composition shown in Table 1.

### Example 3

The treatment agent for inhibiting substrate pattern collapse was prepared as in Example 1 except that a 1% by mass aqueous solution of the surfactant (C-1) was added to the aqueous solution of the polymer (A-1) obtained to have the composition shown in Table 1.

### Example 4

The treatment agent for inhibiting substrate pattern collapse was prepared as in Example 1 except that solvent substitution of the isopropanol solution of the polymer (A-1) obtained in Synthesis Example 1 gave a methanol solution by the use of an evaporator and that the methanol solution of the polymer (A-1) obtained was diluted with methanol to have the composition shown in Table 1.

### Example 5

The treatment agent for inhibiting substrate pattern collapse was prepared as in Example 1 except that the isopropanol solution of the polymer (A-1) obtained in Synthesis Example 1 was diluted with isopropanol to have the composition shown in Table 1.

### Examples 6, 7, 10, 12, 15 and 19 to 23, and Comparative Example 1

Each treatment agent for inhibiting substrate pattern collapse was prepared in a manner similar to that for Example 1 except that each component of the type and the amount shown in Table 1 was used.

### Examples 8, 11, 13, and 14 and Comparative Example 2

Each treatment agent for inhibiting substrate pattern collapse was prepared in a manner similar to that for Example 3 except that each component of the type and the amount shown in Table 1 was used.

### Examples 9 and 16

Each treatment agent for inhibiting substrate pattern collapse was prepared in a manner similar to that for Example 2 except that each component of the type and the amount shown in Table 1 was used.

### Examples 17 and 18, and Comparative Example 3

Each treatment agent for inhibiting substrate pattern collapse was prepared in a manner similar to that for Example 5 except that each component of the type and the amount shown in Table 1 was used.

### Examples 24 to 32

The isopropanol solution of the polymer (A-1) obtained in Synthesis Example 1 was subjected to solvent substitution to replace with the solvent (B) of the type and the amount shown in Table 1, by using an evaporator. The solution of the polymer (A-1) thus obtained was diluted with the solvent (B) to have the composition shown in Table 1. Subsequently, the solution thus obtained was filtered as in Example 1 to prepare each treatment agent for inhibiting substrate pattern collapse.

### Treatment of Substrate

Formation of Coating Film

Each treatment agent for inhibiting substrate pattern collapse prepared in Examples 1 to 32 and Comparative Examples 1 to 3 was applied onto a silicon wafer substrate by using a simplified spin coater (“1H-DX2” available from Mikasa Co., Ltd.) at a rotation speed of 500 rpm in an ambient air. It is to be noted that the silicon wafer used was provided with pillars spaced every 100 nm (reference position: the central portion in the width direction of each pillar) having been densely formed, with the height of each pillar being 380 nm, the width of the upper face of the projecting portion of each pillar being 35 nm, and the width of the cross section at the central portion in the height direction of each pillar being 20 nm. Thereafter, baking was performed on a hot plate at 120° C. for 60 sec to provide each substrate on which a coating film of the treatment agent for inhibiting pattern collapse was formed (Examples 1 to 32 and Comparative Examples 1 to 3).

### Evaluations

The prepared treatment agents for inhibiting pattern collapse were evaluated for the coating property, the embedment property and the ability to inhibit pattern collapse in the following manner.

Coating Property

Each silicon wafer substrate on which the coating film of the treatment agent for inhibiting pattern collapse was formed was visually inspected to determine the presence or absence of streaky defects (striations) extending from the center to the circumference. The coating property was determined to be: “A” (extremely favorable) in a case where no streaky defects (striations) were observed; “B” (favorable) in a case where defects were observed in part of the substrate; and “C” (unfavorable) in a case where defects were observed on the entire face of the substrate. The coating property was not evaluated on Comparative Examples 1 to 3. The results of the evaluations are shown in Table 1.

Embedment Property

Each silicon wafer substrate on which the coating film of the treatment agent for inhibiting substrate pattern collapse was formed was cut away to be seen in cross section, and each treatment agent for inhibiting pattern collapse was evaluated for the embedment property into the pattern by using FE-SEM (“S4800” available from Hitachi High-Technologies Corporation). The embedment property was determined to be: “A” (extremely favorable) in a case where the embedment into the lower part of the pattern was observed, without an exposure of the top part of the pattern; “B” (favorable) in a case where the embedment into the bottom part of the pattern was observed but voids and the like were also observed; and “C” (unfavorable) in a case where a failure of the embedment into the lower part of the pattern was observed, with the exposure of the top part. The embedment property was not evaluated on Comparative Examples 1 to 3. The results of the evaluations are shown in Table 1.

Ability to Inhibit Pattern Collapse

Each silicon wafer substrate on which the coating film of the treatment agent for inhibiting pattern collapse was formed was subjected to an ashing treatment by using an ashing apparatus (“Luminou NA-1300” available from ULVAC Technologies, Inc.) with a gas mixture N₂/H₂ (=97/3 (% by volume)), whereby the embedded treatment agent was removed. The collapse percentage of the pillar substrate after the removal of the film was determined on the basis of an observed image obtained by using the FE-SEM. The ability to inhibit pattern collapse was determined to be: “A” (extremely favorable) in a case where the portion accounting for more than 90% of the pattern escaped collapse; “B” (favorable) in a case where the portion accounting for more than 70% and no greater than 90% of the pattern escaped collapse; and “C” (unfavorable) in a case where the portion accounting for no greater than 70% of the pattern escaped collapse. The results of the evaluations are shown in Table 1.

TABLE 1

| | (A) Polymer | | (B) Solvent | | (C) Additive | | | | |
|---|---|---|---|---|---|---|---|---|---|
| | | Content (parts | | Content (parts | | Content (parts | Coating | Embedment | Ability to Inhibit |
| | Type | by mass) | Type | by mass) | Type | by mass) | Property | property | Pattern Collapse |
| Example 1 | A-1 | 25 | B-1 | 100 | — | — | A | A | A |
| Example 2 | A-1 | 25 | B-1/B-2 | 90/10 | — | — | B | A | A |
| Example 3 | A-1 | 25 | B-1 | 100 | C-1 | 0.1 | A | A | A |
| Example 4 | A-1 | 25 | B-3 | 100 | — | — | B | A | A |
| Example 5 | A-1 | 25 | B-2 | 100 | — | — | B | A | A |
| Example 6 | A-1 | 40 | B-1 | 100 | — | — | A | A | A |
| Example 7 | A-2 | 25 | B-1 | 100 | — | — | A | B | B |
| Example 8 | A-2 | 25 | B-1 | 100 | C-1 | 0.1 | A | A | A |
| Example 9 | A-2 | 25 | B-1/B-2 | 90/10 | — | — | B | A | A |
| Example 10 | A-3 | 15 | B-1 | 100 | — | — | B | B | B |
| Example 11 | A-3 | 15 | B-1 | 100 | C-1 | 0.1 | B | B | B |
| Example 12 | A-4 | 25 | B-1 | 100 | — | — | A | B | B |
| Example 13 | A-4 | 25 | B-1 | 100 | C-1 | 0.1 | A | A | A |
| Example 14 | A-4 | 25 | B-1 | 100 | C-1 | 0.002 | A | A | A |
| Example 15 | A-5 | 25 | B-1 | 100 | — | — | A | A | A |
| Example 16 | A-5 | 25 | B-1/B-2 | 90/10 | — | — | B | A | A |
| Example 17 | A-5 | 5 | B-2 | 100 | — | — | B | A | A |
| Example 18 | A-5 | 40 | B-2 | 100 | — | — | B | A | A |
| Example 19 | A-6 | 20 | B-1 | 100 | — | — | A | B | B |
| Example 20 | A-7 | 20 | B-1 | 100 | — | — | A | B | B |
| Example 21 | A-8 | 20 | B-1 | 100 | — | — | A | B | B |
| Example 22 | A-9 | 5 | B-1 | 100 | — | — | A | B | B |
| Example 23 | A-10 | 5 | B-1 | 100 | — | — | A | B | B |
| Example 24 | A-1 | 25 | B-4 | 100 | — | — | A | A | A |
| Example 25 | A-1 | 25 | B-5 | 100 | — | — | A | A | A |
| Example 26 | A-1 | 25 | B-6 | 100 | — | — | A | A | A |
| Example 27 | A-1 | 25 | B-7 | 100 | — | — | A | A | A |
| Example 28 | A-1 | 25 | B-8 | 100 | — | — | A | A | A |
| Example 29 | A-1 | 25 | B-1/B-4 | 50/50 | — | — | A | A | A |
| Example 30 | A-1 | 25 | B-1/B-7 | 50/50 | — | — | A | A | A |
| Example 31 | A-1 | 25 | B-1/B-4 | 90/10 | — | — | A | A | A |
| Example 32 | A-1 | 25 | B-1/B-7 | 90/10 | — | — | A | A | A |
| Comparative | — | — | B-1 | 100 | — | — | — | — | C |
| Example 1 | | | | | | | | | |
| Comparative | — | — | B-1 | 100 | C-1 | 0.1 | — | — | C |
| Example 2 | | | | | | | | | |
| Comparative | — | — | B-2 | 100 | — | — | — | — | C |
| Example 3 | | | | | | | | | |

As is clear from the results shown in Table 1, the treatment agents for inhibiting substrate pattern collapse of Examples were superior in the coating property, the embedment property and the ability to inhibit pattern collapse.

The treatment agent for inhibiting pattern collapse according to the embodiment of the present invention is capable of inhibiting substrate pattern collapse effectively. The treatment method of a substrate according to the another embodiment of the present invention enables, through the use of the treatment agent for inhibiting pattern collapse, formation of fine structures in which substrate pattern collapse is inhibited. Therefore, the treatment agent and the treatment method may be suitably employed in production methods of fine structures of semiconductor devices in which microfabrication of patterns has been further in progress.

Obviously, numerous modifications and variations of the present invention are possible in light of the above teachings. It is therefore to be understood that within the scope of the appended claims, the invention may be practiced otherwise than as specifically described herein.

What is claimed is:

1. A treatment agent for inhibiting substrate pattern collapse, comprising a polymer and a polar solvent.

2. The treatment agent according to claim 1, wherein the polymer is a hydrophilic polymer.

3. The treatment agent according to claim 1, wherein the polymer comprises a functional group that is a hydroxy group, a carboxy group, an amide group, an amino group, a sulfo group, an aldehyde group or a combination thereof.

4. The treatment agent according to claim 1, wherein the polymer is a vinyl polymer, a polysaccharide, a polyester, a polyether, a polyamide or a combination thereof.

5. The treatment agent according to claim 1, wherein the polymer comprises a hydroxy group-containing vinyl polymer.

6. The treatment agent according to claim 1, wherein a weight average molecular weight of the polymer is no less than 1,000 and no greater than 50,000.

7. The treatment agent according to claim 1, wherein the polar solvent is water or a polar organic solvent.

8. The treatment agent according to claim 7, wherein the polar organic solvent is an alcohol, an alkyl ether of a polyhydric alcohol, a hydroxycarboxylic acid ester, a hydroxy ketone or a combination thereof.

9. The treatment agent according to claim 1, further comprising a surfactant.

10. The treatment agent according to claim 1, wherein a content of the polymer is no less than 0.1% by mass and no greater than 50% by mass in the treatment agent.

11. The treatment agent according to claim 1, which is for use in embedment.

12. A treatment method of a substrate, comprising:
applying a treatment agent which comprises a polymer and a polar solvent onto a substrate having a pattern formed thereon; and
drying the treatment agent applied onto the substrate.

13. The treatment method according to claim 12, wherein the substrate comprises a silicon atom or a metal atom.

14. The treatment method according to claim 12, wherein the polymer is a hydrophilic polymer.

15. The treatment method according to claim 12, wherein the polymer comprises a functional group that is a hydroxy group, a carboxy group, an amide group, an amino group, a sulfo group, an aldehyde group or a combination thereof.

16. The treatment method according to claim 12, wherein the polymer is a vinyl polymer, a polysaccharide, a polyester, a polyether, a polyamide or a combination thereof.

17. The treatment method according to claim 12, wherein the polymer comprises a hydroxy group-containing vinyl polymer.

18. The treatment method according to claim 12, wherein a weight average molecular weight of the polymer is no less than 1,000 and no greater than 50,000.

19. The treatment method according to claim 12, wherein the polar solvent is water or a polar organic solvent.

20. The treatment method according to claim 19, wherein the polar organic solvent is an alcohol, an alkyl ether of a polyhydric alcohol, a hydroxycarboxylic acid ester, a hydroxy ketone or a combination thereof.
